(19) United States
(12) Patent Application Publication
(10) Pub. No.: US 2006/0119371 A1
(43) Pub. Date: Jun. 8, 2006

(54) Semiconductor device and evaluation circuit for the same

(75) Inventor: Kazuyuki Morishige, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/269,766

(22) Filed: Nov. 9, 2005

(30) Foreign Application Priority Data
Nov. 10, 2004 (JP) 2004-326424

(51) Int. Cl. G01R 27/08

(52) U.S. Cl. 324/713

(57) ABSTRACT

An evaluation circuit includes an evaluation pad and a first inverter circuit connected to a first measurement point and a second measurement point to be jointed to first and second power sources, respectively. The first inverter circuit is initialized by an initialization signal from the evaluation pad. The first inverter circuit selectively outputs electric potentials of the first and the second measurement points to the evaluation pad. The circuit further includes a second inverter circuit which has an input connected to the evaluation pad and an output connected to the first inverter circuit. The first and the second inverter circuits are connected in the form of a loop. According to the present invention, the number of evaluation pads can be reduced.

This application claims priority to prior Japanese patent application JP 2004-326424, the disclosure of which is incorporated herein by reference.

### BACKGROUND OF THE INVENTION

1. Field of the Invention

The present invention relates to a semiconductor device which has an evaluation circuit for evaluating an inner circuit included in the semiconductor device and also to the evaluation circuit.

2. Description of the Related Art

More and more functions are being incorporated into electronic equipment and the miniaturization of electronic equipment is advancing. Accordingly, semiconductor devices are allowed to have various functions and are systematized. In addition, trends toward higher integration density of semiconductor devices are advancing. On the other hand, to reduce the size of each semiconductor device, external terminals are limited in number.

Taking this into consideration, it is a recent trend that each semiconductor device is grouped into a plurality of functional blocks most of which have input and output terminals that are not provided as external terminals but are embedded only within the semiconductor device.

When a semiconductor device has external terminals, the characteristics of the semiconductor device can be directly confirmed through the external terminals. However, the characteristics thereof cannot be directly confirmed or investigated when no external terminals exist. Accordingly, it is very difficult to evaluate and inspect the semiconductor device. In particularly, in evaluating the semiconductor device, if any problem or failure is found in the semiconductor device, it is necessary to specify or detect a failure portion which might be present in either a functional block or a circuit in the semiconductor device. Thereafter, such a problem should be remedied at the detected failure portion. However, as the semiconductor device is systemized and more functional blocks are incorporated thereinto, direct evaluation or inspection becomes difficult with an increase of that input and output terminals of functional blocks which do not appear as the external terminals. This shows that it is difficult to specify a portion having a problem also.

Further, in current semiconductor devices, various different voltages, such as a high voltage, a low voltage, and a reference voltage, are generated in each semiconductor device in addition to a power supply voltage externally supplied. The requirement on precision for each internally generated voltage value is strict. A slight deviation from a design value causes a malfunction of a semiconductor device or an operation margin failure. Therefore, it is very important to confirm internally generated voltages. Unfortunately, in many cases, since no external terminals are provided, it is difficult to evaluate internally generated voltages.

As a result, semiconductor devices cannot be sufficiently evaluated and inspected due to absence of the external terminals. To overcome such a disadvantage, evaluation pads are arranged so as to correspond to respective points whose potentials are to be measured (hereinbelow, referred to points to be measured) in a semiconductor device to evaluate the device. However, as the number of functional blocks and the number of internally generated voltages are larger, the number of evaluation pads also becomes larger. Disadvantageously, the total area of evaluation pads is increased.

There are several related arts regarding evaluation pads. For example, Japanese Unexamined Patent Application Publication No. 2004-117168 (hereinbelow, referred to as Patent Document 1) discloses a semiconductor integrated circuit including evaluation pads and selectors. Upon evaluation, an evaluation pad is selected to define a connection route from an external terminal and the evaluation pad is connected to the external terminal. Thus, the semiconductor device is evaluated in the Patent Document 1.

Japanese Unexamined Patent Application Publication No. 09-51073 (Patent Document 2) discloses a semiconductor integrated circuit in which a control transistor for evaluation and an evaluation pad are provided at an input side of an output circuit and the evaluation pad turns the evaluation control transistor on or off to change an output level.

Japanese Unexamined Patent Application Publication No. 2001-217390 (Patent Document 3) discloses a semiconductor integrated circuit in which evaluation pads are arranged in a free space on a chip and the pads are connected to an element to be evaluated, through an energy beam. Thus, evaluating the element is carried out by the use of the energy beam in the Patent Document 3.

According to Patent Documents 1 and 2 mentioned above, it is necessary to provide a plurality of evaluation pads corresponding to points to be measured in a semiconductor device. Both of them are disadvantageous in that evaluation pads are increased in number and such an increase of the evaluation pads results in an increase of the total area of pads. According to Patent Document 3, a special device is required to connect the evaluation pads to the element.

### SUMMARY OF THE INVENTION

The present invention is made in consideration of the above-mentioned disadvantages.

It is therefore an object of the present invention to provide a semiconductor device including an evaluation circuit capable of evaluating a plurality of points to be measured, by using one evaluation pad, to reduce the number of evaluation pads and also provide the evaluation circuit.

According to a first aspect of the present invention, an evaluation circuit comprises an evaluation pad and a first inverter circuit including a first measurement point to be connected to a first power source, and a second measurement point to be connected to a second power source. The first inverter circuit is initialized by an initialization signal from the evaluation pad, and the first inverter circuit is operable to selectively supply the evaluation pad with electric potentials at the first and the second measurement points.

According to a second aspect of the present invention, the evaluation circuit further comprises a second inverter circuit which has an input connected to the evaluation pad and an output connected to the first inverter circuit. The first and second inverter circuits are connected in the form of a loop and each of the first and second circuits is initialized by the initialization signal to maintain the initial state thereof.

According to a third aspect of the present invention, when the initialization signal takes a high level, the first inverter circuit outputs an electric potential of the first measurement point to the evaluation pad, and when the initialization signal takes a low level, the first inverter circuit outputs an electric potential of the second measurement point to the evaluation pad.

According to a fourth aspect of the present invention, potentials are set at the first and second measurement points and the first inverter circuit is thereafter initialized by the initialization signal to selectively output the electric potentials of the first and the second measurement points to the evaluation pad.

According to a fifth aspect of the present invention, the first inverter circuit is initialized by the initialization signal and the electric potentials are set to the first and second measurement points to make the first inverter circuit selectively output the electric potentials from the first and the second measurement points to the evaluation pad.

According to a sixth aspect of the present invention, the electric potential at the first measurement point is higher than that at the second measurement point and the difference between the electric potentials at the first measurement point and that at the second measurement point is equal to or higher than a threshold voltage of the first inverter circuit.

According to a seventh aspect of the present invention, an evaluation circuit comprises a plurality of evaluation pads, a plurality of evaluation blocks each including a first inverter circuit and a second inverter circuit connected to each other in the form of a loop, and switching circuits each for switching condition and non-conduction between the corresponding evaluation pad and the corresponding evaluation block.

According to an eighth aspect of the present invention, a semiconductor device comprises the evaluation circuit mentioned in connection with either one the first through the seventh aspects.

According to a ninth aspect of the present invention, an evaluation circuit comprises an evaluation pad, a plurality of measurement points to be measured by the evaluation circuit, and an electric circuit for selectively connecting each of the plurality of the measurement points to the evaluation pad.

According to a tenth aspect of the present invention, the plurality of the measurement points comprises first and second measurement points to be given first and second electric potentials different from each other. The electric circuit comprises a first inverter circuit between the evaluation pad and the first and the second measurement points to selectively connect the first and the second measurement points to the evaluation pad.

According to an eleventh aspect of the present invention, the electric circuit further comprises a second inverter circuit connected to the evaluation pad and connected to the first inverter circuit in the form of a loop.

According to a twelfth aspect of the present invention, the second inverter circuit is connected to third and fourth measurement points common to the first and the second measurement points, respectively.

According to a thirteenth aspect of the present invention, a method is for use in evaluating a semiconductor device by the use of an evaluation circuit having an evaluation pad. The method comprises the steps of providing a plurality of measurement points to be measured by the evaluation circuit, selectively connecting each of the measurement points to the evaluation pad to monitor electric potentials of the respective measurement points, and monitoring a potential at the evaluation pad.

With the above structure, a plurality of measurement points to be measured can be evaluated using one evaluation pad. Advantageously, the number of evaluation pads can be reduced.

### BRIEF DESCRIPTION OF THE DRAWINGS

FIG. 1 is a block diagram of an evaluation circuit according to a first embodiment of the present invention;

FIG. 2 is a circuit diagram showing an example of an inverter circuit in the evaluation circuit in FIG. 1;

FIG. 3 is a timing chart of the evaluation circuit in FIG. 1;

FIG. 4 is another timing chart of the evaluation circuit in FIG. 1; and

FIG. 5 is a block diagram of an evaluation circuit according to a second embodiment of the present invention.

### DESCRIPTION OF THE PREFERRED EMBODIMENTS

A semiconductor device and an evaluation circuit according to the present invention will now be described hereinbelow with reference to the drawings.

### First Embodiment

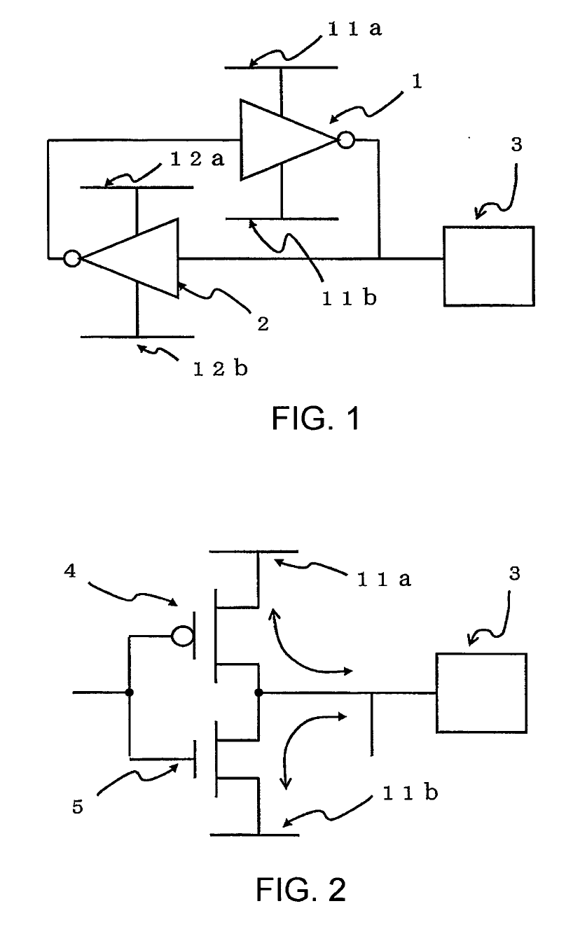

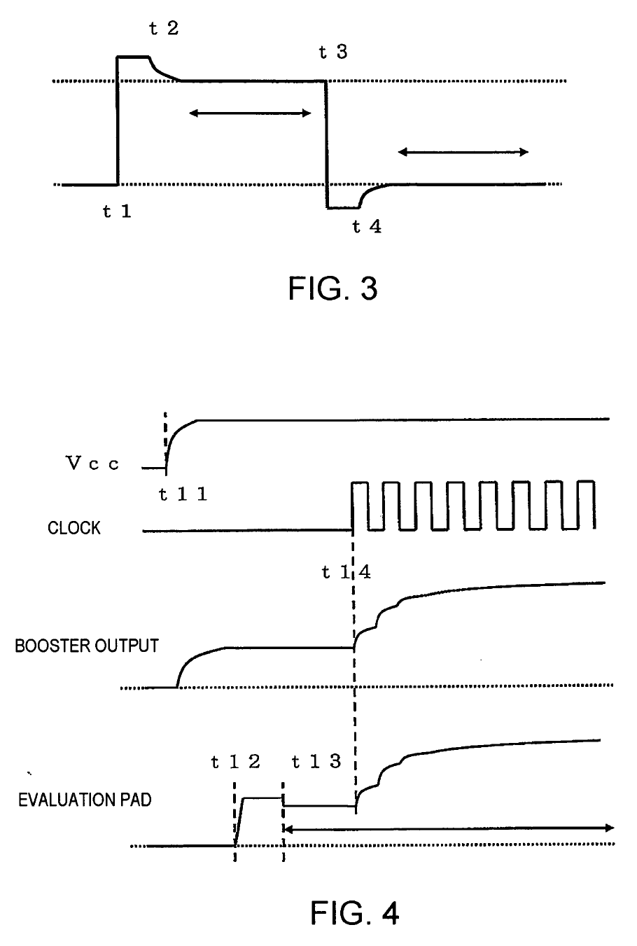

A first embodiment of the present invention will now be explained with reference to FIGS. 1 to 4. FIG. 1 is a block diagram of an evaluation circuit. FIG. 2 is a circuit diagram showing an example of an inverter circuit in the evaluation circuit. FIG. 3 shows a timing chart of the evaluation circuit. FIG. 4 shows another timing chart of the evaluation circuit.

Referring to FIG. 1, the evaluation circuit includes an inverter circuit 1 arranged between a first power source or supply 11a and a second power source 11b, an inverter circuit 2 arranged between a third power source 12a and a fourth power source 12b, and an evaluation pad 3. The inverter circuits 1 and 2 are connected to each other in the form of a loop. Specifically, the input of the inverter circuit 1 is connected to the output of the inverter circuit 2. The output of the inverter circuit 1 is connected to the input of the inverter circuit 2. The output of the inverter circuit 1 is also connected to the evaluation pad 3. In some cases, the inverter circuits 1 and 2 may also be called evaluation blocks.

The inverter circuit 2 inverts an initialization signal supplied from the evaluation pad 3 and outputs the inverted signal to the inverter circuit 1. Both the inverter circuits 1 and 2 serve to maintain an initialization mode and/or an initial state. Specifically, the inverter circuit 2 is operable as an initialization circuit for initial setting.

To initialize the evaluation circuit, the initialization signal is given to the inverter circuit 2 from the evaluation pad 3. Responsive to the initialization signal, the inverter circuit 2 is set in an initial state. The output of the inverter circuit 2 sets a state of the inverter circuit 1, so that the initialization signal is held by the inverter circuits 1 and 2.

Each of the first and second power sources 11 a and 11 b of the inverter circuit 1 and the third and fourth power sources 12a and 12b of the inverter circuit 2 supplies a power supply voltage. To operate the respective inverter circuits 1 and 2, it is assumed in this example that the power supply potential of the first power source 11 a is higher than that of the second power source 11b and the power supply potential of the third power source 12a is higher than that of the fourth power source 12b. Each of the potential differences is preferably equal to or higher than a threshold voltage of the corresponding inverter circuit.

The first power source 11a of the inverter circuit 1 is connected to a first point to be measured (may be called a first measurement point) and the second power source 11b thereof is connected to a second point to be measured (may be called a second measurement point). Therefore, the respective power sources serve as points or nodes to be measured (namely, measurement points or nodes). In other words, the respective power sources are connected to the measurement points, respectively.

The inverter circuit 1 supplies a high-level to the evaluation pad 3 as a voltage or potential level of the first measurement point and supplies a low-level to the evaluation pad 3 as a voltage level of the second measurement point. Likewise, the third power source 12a of the inverter circuit 2 is connected to the first measurement point and the fourth power source 12b thereof is connected to the second measurement point. In this case, the connection of the power sources to the inverter circuit 2 is similar to that to the inverter circuit 1 and may be done with a power supply potential Vcc of an external power source and a ground potential GND. This shows that the inverter circuit may be given electrical potentials that can be operated as inverters and which are not limited to the above-mentioned potentials.

The operation of the evaluation circuit will now be described with reference to FIGS. 2 to 4. FIG. 2 shows a CMOS inverter circuit as an example of the inverter circuit 1. The CMOS inverter circuit includes a PMOS transistor 4 and an NMOS transistor 5. FIG. 3 shows a timing chart in a case where after potential levels at measurement points are set, the evaluation circuit is initialized and the evaluation operation is performed. FIG. 4 shows a timing chart in a case where potential levels at points to be measured (measurement points) are determined after the initialization of the evaluation circuit.

Referring to FIG. 3, a high-level voltage is externally supplied to the evaluation pad 3 at time t1. The inverter circuit 2, which receives a high-level signal, outputs a low-level signal. The inverter circuit 1, loop-connected to the inverter circuit 2, outputs a high-level signal. Thus, the evaluation circuit is initialized. At time t2, the supply of the high-level voltage is stopped. Consequently, a potential of the first measurement point is output to the evaluation pad 3 via the PMOS transistor 4 in the inverter circuit 1 and the potential is maintained. As mentioned above, the potential of the first measurement point is output as a high-level signal of the inverter circuit 1 to the evaluation pad 3. Thus, the potential of the first measurement point can be measured and evaluated.

At time t3, a low-level voltage is externally supplied to the evaluation pad 3. The inverter circuit 2, which receives a low-level signal, outputs a high-level signal. The inverter circuit 1, loop-connected to the inverter circuit 2, outputs a low-level signal. Thus, the evaluation circuit is initialized to an inverted output state. At time t4, the supply of the low-level voltage is stopped. Consequently, a signal at a potential of the second measurement point is output to the evaluation pad 3 via the NMOS transistor 5 in the inverter circuit 1 and the potential is maintained. As mentioned above, a potential of the second measurement point is output as a low-level signal of the inverter circuit 1 to the evaluation pad 3. Thus, the potential at the second measurement point can be measured and evaluated.

A high-level voltage is supplied to the evaluation pad 3 for a period between time t1 and time t2 and a low-level voltage is supplied to the evaluation pad 3 for a period between time t3 and time t4. Thus, the evaluation circuit is initialized. Consequently, potentials at the first and second measurement points can be evaluated by using the single evaluation pad 3. Judgment is made by monitoring the evaluation pad 3 about whether or not a signal has a level equal to a design value. For example, if a logical error is present, an output level differs from an expected value. In addition, when a reference voltage is deviated from the design value, a voltage corresponding to the deviation can be measured.

FIG. 4 shows another timing chart of the evaluation circuit. In this case, after the evaluation circuit is initialized, potential levels at the measurement points are determined. Since potential changes can be monitored until potentials at the measurement points are established, effective dynamic analysis can be executed. In this case, it is assumed that a booster circuit is used in the illustrated example. An output of the booster circuit is connected to the first power source 11‘a and the ground potential of the booster circuit is connected to the second power source 11b.

At time t11, an external power voltage Vcc of a semiconductor device starts to be supplied and increases to a predetermined value. The output of the booster circuit also goes to a power supply voltage level. For a period between time t12 and time t13, a high-level voltage is applied to the evaluation pad 3 to initialize the evaluation circuit. At time t13, the initialization is finished and the evaluation pad 3 is held at the output level of the booster circuit. At time t14, the voltage-boosting operation of the booster circuit is started due to a clock pulse. The voltage-boosting operation of the booster circuit can be measured over time. Since the detailed operation of the booster circuit can be measured, therefore, evaluation can be easily made. Although not shown, when a low-level voltage is similarly applied to the evaluation pad 3 to initialize the evaluation circuit, the ground potential of the booster circuit connected to the second power source 11 b can be evaluated.

According to the present embodiment, the evaluation circuit includes one evaluation pad, the first inverter circuit having a first power source, providing the first measurement point, and the second power source, providing the second measurement point, and the second inverter circuit, serving as an initialization circuit, connected to the first inverter circuit in a loop. When the potential of the first inverter circuit in the evaluation circuit is initialized to a high level or a low level, a potential at the first measurement point or that at the second measurement point can be alternately evaluated. With the above configuration, it is possible to obtain a semiconductor device in which potentials at a plurality of measurement points can be evaluated by using a single evaluation pad.

### Second Embodiment

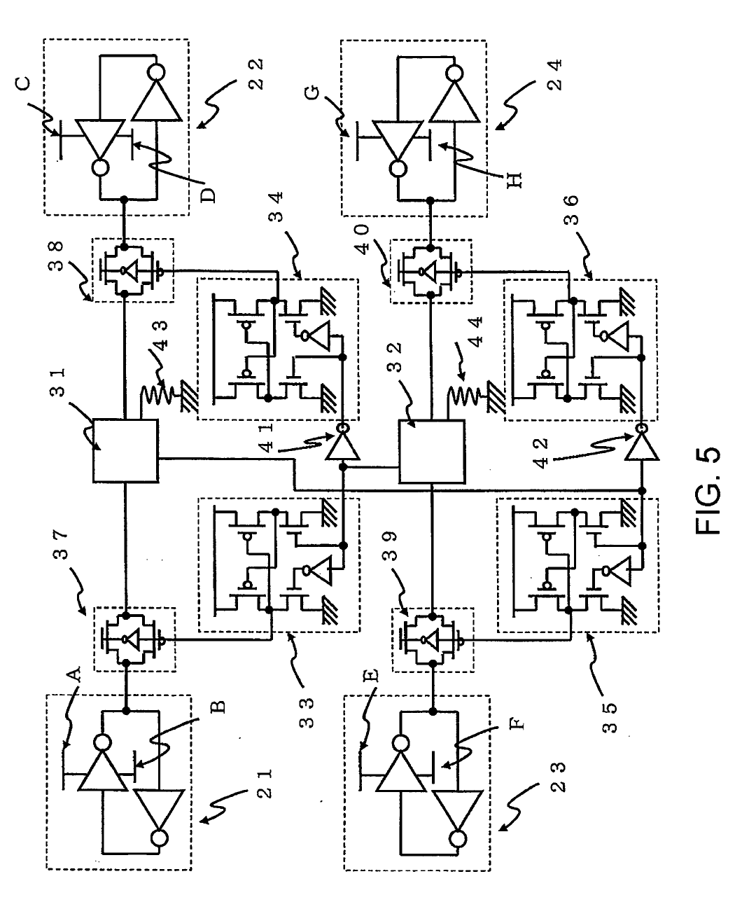

According to a second embodiment of the present invention, connections between evaluation pads and measurement points are switched between conduction and non-conduction through transfer gates. This structure results in a reduction in the number of evaluation pads. FIG. 5 is a block diagram of an evaluation circuit according to the second embodiment. Table 1 shows the combinations of initialization levels and measurement points.

Referring to FIG. 5, the evaluation circuit includes two evaluation pads 31 and 32 and four evaluation blocks 21 to 24. Eight measurement points A to H to be measured are connected to power sources A to H of inverter circuits in the respective evaluation blocks. Potentials at the respective points A to H can be evaluated.

The evaluation blocks 21 and 22 are connected to the evaluation pad 31 via transfer gates 37 and 38, respectively. The transfer gate 37 is switched between conduction and non-conduction by a signal which is obtained by converting the level of an initialization signal supplied from the evaluation pad 32 through a level conversion circuit 33. The transfer gate 38 is switched between conduction and non-conduction by a signal which is obtained by inverting the initialization signal from the evaluation pad 32 through an inverter circuit 41 and converting the level of the inverted signal through a level conversion circuit 34.

The evaluation blocks 23 and 24 are connected to the evaluation pad 32 via transfer gates 39 and 40, respectively. The transfer gate 39 is switched between conduction and non-conduction by a signal which is obtained by converting the level of an initialization signal from the evaluation pad 31 through a level conversion circuit 35. The transfer gate 40 is switched between conduction and non-conduction by a signal which is obtained by inverting the initialization signal from the evaluation pad 31 through an inverter circuit 42 and converting the level of the inverted signal through a level conversion circuit 36.

Each transfer gate connects the source of a PMOS transistor to the drain of an NMOS transistor, supplies a signal from the corresponding level conversion circuit to the gate of the PMOS transistor, and supplies an inverted signal of the above signal to the gate of the NMOS transistor. Each level conversion circuit cooperates with the corresponding transfer gate to put the latter into a sufficient conduction state and prevents a reduction in potential at a measurement point. Preferably, each level conversion circuit is constructed such that the highest potential and the lowest potential of a semiconductor device can be output. Each of pull-down resistors 43 and 44 fixes the potential of the evaluation circuit to a low level when the corresponding evaluation pad is not used. Any means capable of fixing a potential level is available.

TABLE 1

| | |
|---|---|
| INITIALIZATION | POINT TO BE MEASURED |

| PAD 31 | PAD 32 | PAD 31 | PAD 32 |
|---|---|---|---|
| LOW | LOW | B | F |
| LOW | HIGH | D | E |
| HIGH | LOW | A | H |
| HIGH | HIGH | C | G |

The operation of the evaluation circuit according to the second embodiment will now be described with reference to FIG. 5 and Table 1. When a low-level signal is supplied as an initialization signal to each of the evaluation pads 31 and 32, each of the level conversion circuits 33 and 35 outputs a low-level signal and each of the transfer gates 37 and 39 is put into a conduction state. Each of the level conversion circuits 34 and 36 outputs a high-level signal and each of the transfer gates 38 and 40 is put into a non-conduction state. The evaluation pad 31 is connected to the evaluation block 21 to evaluate a potential at the point B. The evaluation pad 32 is connected to the evaluation block 23 to evaluate a potential at the point F.

Similarly, when a low-level signal and a high-level signal are supplied as initialization signals to the evaluation pads 31 and 32, respectively, the evaluation pads 31 and 32 can evaluate potentials at the points D and E, respectively. When a high-level signal and a low-level signal are supplied as initialization signals to the evaluation pads 31 and 32, respectively, the evaluation pads 31 and 32 can evaluate potentials at the points A and H, respectively. In addition, when a high-level signal is supplied as an initialization signal to each of the evaluation pads 31 and 32, the evaluation pads 31 and 32 can evaluate potentials at the points C and G, respectively.

As mentioned above, according to the present embodiment, two evaluation pads can evaluate potentials at eight points connected to eight power sources of respective evaluation blocks. Therefore, the number of evaluation pads can be reduced.

According to the present embodiment, the evaluation circuit includes two evaluation pads and four evaluation blocks. The connections between the evaluation pads and the evaluation blocks are controlled between conduction and non-conduction by initialization signals, thus evaluating potentials at eight points. With the above configuration, it is possible to obtain a semiconductor device in which potentials at a plurality of points can be evaluated by each evaluation pad.

While the present invention has been described in terms of its preferred embodiments, it should be understood that the present invention is not limited to those embodiments and various changes and modifications thereof could be made without departing from the spirit or scope of the invention. For example, the evaluation circuit may not be restricted to the inverter or inverters but may include an electric circuit, such as a selection circuit, for selectively connect a plurality of measurement points or node to each evaluation node.

What is claimed is:

1. An evaluation circuit comprising:
an evaluation pad; and
a first inverter circuit including a first measurement point to be connected to a first power source, and a second measurement point to be connected to a second power source, wherein
the first inverter circuit is initialized by an initialization signal from the evaluation pad, and
the first inverter circuit is operable to selectively supply the evaluation pad with electric potentials at the first and the second measurement points.

2. The circuit according to claim 1, further comprising:
a second inverter circuit which has an input connected to the evaluation pad and an output connected to the first inverter circuit, wherein
the first and second inverter circuits are connected in the form of a loop and
each of the first and second circuits is initialized by the initialization signal to maintain the initial state thereof.

3. The circuit according to claim 2, wherein
when the initialization signal takes a high level, the first inverter circuit outputs an electric potential of the first measurement point to the evaluation pad, and
when the initialization signal takes a low level, the first inverter circuit outputs an electric potential of the second measurement point to the evaluation pad.

4. The circuit according to claim 1, wherein potentials are set at the first and second measurement points and the first inverter circuit is thereafter initialized by the initialization signal to selectively output the electric potentials of the first and the second measurement points to the evaluation pad.

5. The circuit according to claim 1, wherein the first inverter circuit is initialized by the initialization signal and the electric potentials are set to the first and second measurement points to make the first inverter circuit selectively output the electric potentials from the first and the second measurement points to the evaluation pad.

6. The circuit according to claim 1, wherein the electric potential at the first measurement point is higher than that at the second measurement point and the difference between the electric potentials at the first measurement point and that at the second measurement point is equal to or higher than a threshold voltage of the first inverter circuit.

7. An evaluation circuit, comprising:
a plurality of evaluation pads;
a plurality of evaluation blocks each including a first inverter circuit and a second inverter circuit connected to each other in the form of a loop; and
switching circuits each for switching condition and non-conduction between the corresponding evaluation pad and the corresponding evaluation block.

8. A semiconductor device comprising the evaluation circuit according to any one of claims 1 to 7.

9. An evaluation circuit comprising:
an evaluation pad;
a plurality of measurement points to be measured by the evaluation circuit; and
an electric circuit for selectively connecting each of the plurality of the measurement points to the evaluation pad.

10. The evaluation circuit claimed in claim 9, wherein the plurality of the measurement points comprises first and second measurement points to be given first and second electric potentials different from each other;
the electric circuit comprising a first inverter circuit between the evaluation pad and the first and the second measurement points to selectively connect the first and the second measurement points to the evaluation pad.

11. The evaluation circuit claimed in claim 10, wherein the electric circuit further comprises a second inverter circuit connected to the evaluation pad and connected to the first inverter circuit in the form of a loop.

12. The evaluation circuit claimed in claim 11, wherein the second inverter circuit is connected to third and fourth measurement points common to the first and the second measurement points, respectively.

13. A method of evaluating a semiconductor device by the use of an evaluation circuit having an evaluation pad, comprising the steps of:
providing a plurality of measurement points to be measured by the evaluation circuit;
selectively connecting each of the measurement points to the evaluation pad to monitor electric potentials of the respective measurement points, and monitoring a potential at the evaluation pad.
